(19) United States
(12) Patent Application Publication
(10) Pub. No.: US 2023/0351310 A1
(43) Pub. Date: Nov. 2, 2023

(54) PLATFORM FOR SHIPPING LOGISTICS SIMULATION AND EXECUTION

(71) Applicant: X Development LLC, Mountain View, CA (US)

(72) Inventors: Grigory Bronevetsky, San Ramo, CA (US); Salil Vijaykumar Pradhan, San Jose, CA (US); John Michael Stivoric, Pittsburgh, PA (US); Randolph Preston McAfee, San Marino, CA (US); Sze Man Lee, Milpitas, CA (US); Christine Grace Haaf, San Francisco, CA (US)

(21) Appl. No.: 18/193,045

(22) Filed: Mar. 30, 2023

Related U.S. Application Data
(60) Provisional application No. 63/325,583, filed on Mar. 30, 2022.

(51) Int. Cl. G06Q 10/083; G06F 30/20

(52) U.S. Cl. CPC G06Q 10/083; G06F 30/20

(57) ABSTRACT

Methods, systems, and apparatus, including computer programs encoded on computer storage media, for planning shipping logistics routes. A computer-implemented method includes: receiving a request for a first shipment to occur during a first time duration, the request being provided by a requestor; obtaining shipment data representing scheduled shipments to occur during a second time duration, the second time duration overlapping the first time duration; providing the request for the first shipment and the shipment data as input to a shipping model; obtaining, as output from the shipping model, simulation results including predicted shipments during the second time duration, the predicted shipments including the first shipment and the scheduled shipments, the simulation results including predicted movements of shipping resources executing the predicted shipments during the second time duration; and assigning shipping resources to the predicted shipments based on the simulation results.

### CROSS REFERENCE TO RELATED APPLICATION

This application claims the benefit of U.S. Provisional Pat. Application No. 63/325,583, filed Mar. 30, 2022, the contents of which are incorporated by reference herein.

### TECHNICAL FIELD

This specification relates generally to transportation and shipping.

### BACKGROUND

Shipping logistics involves a highly complex nature of operations and numerous operational constraints. Shipping routing is impacted by dynamically changing environmental, mechanical, and logistical factors. This complexity can result in inefficient operation of shipping vehicles, which results in undesirable expenditure of resources, such as energy (e.g., fuel, electricity). It is not possible to efficiently manage fuel consumption of shipping vehicles while also ensuring that shipping schedules meet user requirements of cost and service levels while balancing capacity requirements.

### SUMMARY

This specification describes techniques, methods, systems, and other approaches for simulating, planning, and executing shipping logistics routes, using new techniques and data to provide data insights that have not been previously available or possible. A shipping logistics planning platform can be implemented to build and operate supply chains. The platform can be used to model and stress test an end-to-end supply chain in order to find fragility. The platform can also use adversarial models to find solutions to improve robustness of the supply chain. Thus, antifragility can be built into the supply chain.

The world’s supply chains are interconnected and dependent on numerous external variables, from weather and economic cycles to consumer sentiment. As such the supply chains form a chaotic system and can be unpredictable. Supply chain systems are often focused on predicting an outcome and then optimizing around the predictions. When unexpected events occur, the effects may range from minor delays to system-wide breakdowns in supply chains. The disclosed implementations can be used to focus on modeling and reducing supply chain fragility.

A supply chain planning platform can capture the distribution of the possible ways in which supply chains may be driven, develop conditional plans for how participants productively respond to each scenario, and proactively plan to ensure the responses are likely to be available when needed, with probability commensurate with their importance.

For example, consider the scenario of supplying local stores with bottles of sparkling water. The supply chain is driven by the availability of sparkling water in regional warehouses and the amount of stock remaining in each store, both of which depend on other parts of the supply chain. The supply chain planning platform can enumerate all the relevant scenarios of warehouse/store inventory and truck availability. For each scenario, the platform can formulate an appropriate supply chain execution plan. Finally, the platform can consider the probability distribution of all these scenarios and design a comprehensive plan that maximizes the probability of successful execution at a low cost. Thus, the platform can be implemented to improve the robustness and efficiency of road transportation within supply chains.

In general, innovative aspects of the subject matter described in this specification can be embodied in methods including actions of receiving a request for a first shipment to occur during a first time duration, the request being provided by a requestor; obtaining shipment data representing scheduled shipments to occur during a second time duration, the second time duration overlapping the first time duration; providing the request for the first shipment and the shipment data as input to a shipping model; obtaining, as output from the shipping model, simulation results including predicted shipments during the second time duration, the predicted shipments including the first shipment and the scheduled shipments, the simulation results including predicted movements of shipping resources executing the predicted shipments during the second time duration; and assigning shipping resources to the predicted shipments based on the simulation results.

In some implementations, the actions include determining a likelihood of cancelation of the first shipment, including: providing, for presentation on a display of a computing device, a plurality of shipment offers; receiving, from the computing device, data indicating a selected offer of one of the plurality of shipment offers; and determining, based on the selected offer, a likelihood that the first shipment will be canceled by the requestor.

In some implementations, providing, for presentation on the display of the computing device, the plurality of shipment offers comprises generating a graphical user interface displaying selectable icons, each selectable icon being associated with a different one of the plurality of shipment offers, and receiving, from the computing device, the data indicating the selected offer of one of the plurality of shipment offers includes receiving, through the graphical user interface, data indicating a selection, by the requestor, of one of the selectable icons.

In some implementations, each shipment offer includes: a total cost value of the first shipment; a value of a deposit for reserving the first shipment; and a time when the deposit is due for reserving the first shipment.

In some implementations, determining, based on selected offer, the likelihood that the first shipment will be canceled by the requestor includes: providing, as input to a shipment cancelation model, the selected offer; and receiving, as output from the shipment cancelation model, the likelihood that the first shipment will be canceled by the requestor.

In some implementations, the simulation results include, for each predicted shipment, a likelihood that the predicted shipment will be canceled by the requestor.

In some implementations, the shipping model includes a shipment cancelation model configured to determine probabilities of cancelation of shipments, the actions including: determining, for each of a plurality of reserved shipments and using the shipment cancelation model, cancelation prediction data indicating a likelihood that the reserved shipment will be canceled by the requestor; obtaining cancelation data indicating, for each of the plurality of reserved shipments, whether the reserved shipment was canceled by the requestor; determining an error between the cancelation prediction data and the cancelation data; and adjusting parameters of the shipment cancelation model based on the error between the cancelation prediction data and the cancelation data; and determining, using the shipment cancelation model, a likelihood that each of the predicted shipments will be canceled by the requestor.

In some implementations, determining, for each of the plurality of reserved shipments and using the shipment cancelation model, the cancelation prediction data indicating the likelihood that the reserved shipment will be canceled by the requestor includes: providing, as input to the shipment cancelation model, a shipment offer selected for each of the plurality of reserved shipments.

In some implementations, the actions include: after the second time duration, determining movements of the shipping resources that occurred during the second time duration, including: determining, for each predicted movement whether the predicted movement occurred, and; determining for each of the predicted movements that occurred, a respective time that the predicted movement occurred; determining an error between the movements of the shipping resources that occurred during the second time duration and the predicted movements of the shipping resources during the second time duration; and adjusting parameters of the shipping model based on the error between the movements of the shipping resources during the second time duration and the predicted movements of the shipping resources during the second time duration.

In some implementations, the simulation results include, for each of the predicted shipments, a probability function of whether or not the shipment will occur.

In some implementations, the request for the first shipment includes at least one of: a type of goods to be shipped; a quantity of goods to be shipped; a first resource needed to execute the first shipment; a first location from which the goods are to be shipped; a second location to which the goods are to be shipped a target start time for the first shipment; or a target time for delivery of the goods to the second location.

In some implementations, the shipping model includes a resource availability model, the actions including determining a likelihood of execution of the first shipment based on availability of resources, including: providing, as input to the resource availability model, the request for the first shipment; obtaining, as output from the resource availability model, a likelihood that the first resource will be available at the first location at or before the target start time; and determining, based on the likelihood that the first resource will be available at the first location at or before the target start time, the likelihood of execution of the first shipment.

In some implementations, determining the likelihood of execution of the first shipment includes: determining the likelihood that the first resource will be available at the first location at or before the target start time; and determining the likelihood of cancelation of the first shipment.

In some implementations, the actions include: determining, for each of a plurality of reserved shipments and using a resource availability model, resource prediction data indicating a likelihood that a resource needed to execute the reserved shipment will be available to execute the reserved shipment; obtaining availability data indicating, for each of the plurality of reserved shipments, whether the resource needed to execute the reserved shipment was available to execute the reserved shipment; determining an error between the resource prediction data and the availability data; and adjusting parameters of the resource availability model based on the error between the resource prediction data and the availability data; and determining, using the resource availability model, a likelihood that each of the predicted shipments will be executed.

In some implementations, each predicted shipment includes a movement of at least one shipping resource; and the simulation results include predicted locations of shipping resources during the second time duration.

In some implementations, the first time duration includes a portion of a day and the second time duration includes the day; or the first time duration includes a day and the second time duration includes a plurality of days.

In some implementations, the simulation results include, for each predicted shipment, at least one of: a type of goods to be shipped; a quantity of goods to be shipped; a resource needed to execute the predicted shipment; a first location from which the goods are to be shipped; a second location to which the goods are to be shipped; a target start time for the predicted shipment; or a target time for delivery of the goods to the second location.

In some implementations, assigning shipping resources to the predicted shipments includes assigning an autonomous vehicle to a first predicted shipment, the actions including: transmitting, to a communications device of the autonomous vehicle using wireless communications, instructions to transit to the first location for arrival at or before the target start time for the first predicted shipment.

The subject matter described in this specification can be implemented in various embodiments and may result in one or more of the following advantages. The disclosed implementations can be used improve schedule reliability, vehicle, shipping capacity, and fuel consumption. Thus, implementations may reduce environmental impacts of shipping vehicles, such as reduced resource consumption, while improving operational efficiency and reducing costs of operating the shipping vehicles. The disclosed techniques provide various computational advantages. For example, many computing nodes are used to perform large numbers (e.g., millions) of simulation operations. The results are processed into a usable form to predict shipping activities and movements. New data sources are accessed that have not previously been available. The new data sources are used to provide new data insights. Accurate logistical models are then generated using smaller amounts data that previously possible. This results in highly accurate simulation models. The simulation models can be used to provide high simulation throughput and more accurate simulation results. Simulation models are automatically trained and updated with real time or near real time information, improving accuracy and reliability over time.

Implementations include systems, apparatus, and computer programs, configured to perform the actions of the methods disclosed herein, encoded on computer storage devices. The present disclosure also provides a computer-readable storage medium coupled to one or more processors and having instructions stored thereon which, when executed by the one or more processors, cause the one or more processors to perform operations in accordance with implementations of the methods provided herein.

The present disclosure further provides a system for implementing the methods provided herein. The system includes one or more processors, and a computer-readable storage medium coupled to the one or more processors having instructions stored thereon which, when executed by the one or more processors, cause the one or more processors to perform operations in accordance with implementations of the methods provided herein.

It is appreciated that methods in accordance with the present disclosure can include any combination of the aspects and features described herein. That is, methods in accordance with the present disclosure are not limited to the combinations of aspects and features specifically described herein, but also include any combination of the aspects and features provided.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 illustrates an example system for shipping logistics simulation, planning, and execution.

FIG. 2 is a flow diagram of an example process for supply chain logistics planning.

FIGS. 3A to 3C show example land and sea shipping routes of a shipment of goods.

Like reference numbers and designations in the various drawings indicate like elements.

### DETAILED DESCRIPTION

In general, a shipping system includes two types of agents: customers (e.g., shippers) who need goods shipped between locations, and shipping companies that provide infrastructure (e.g., trucks, ships, intermediate warehouses) to perform this service. Additionally, there are trucking companies, drivers, intermediary organizations, companies that aggregate demand, companies that monitor drivers, and technology providers.

An effective system for managing shipping ships confidently and efficiently. Shippers need some confidence that they will get shipping services when they require the services. Shipping that is more reliable, faster, or more specialized costs more. Higher value shipments are delivered more reliably than lower value shipments.

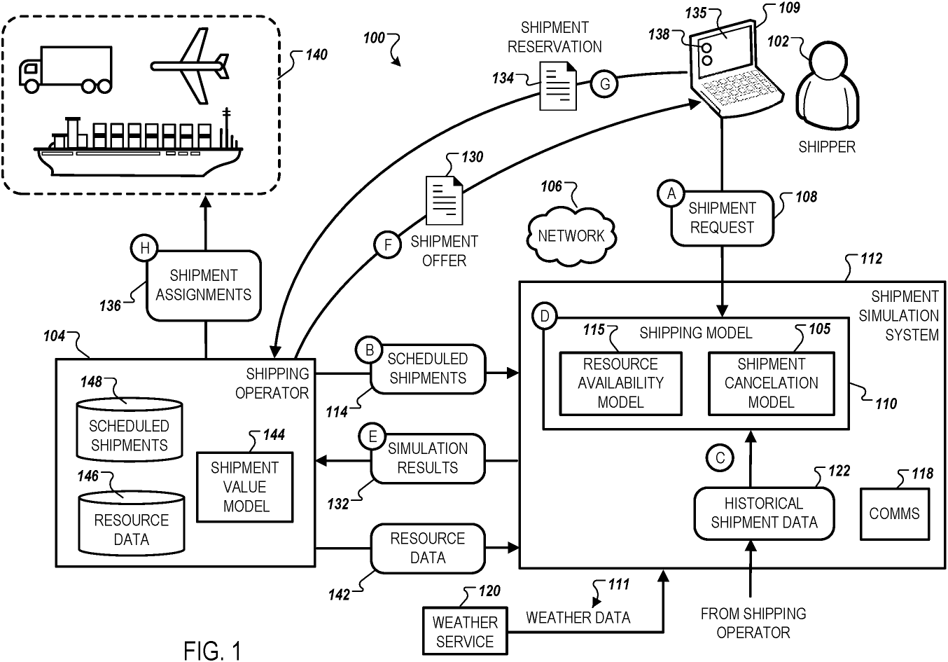

FIG. 1 illustrates an example system for shipping logistics simulation, planning, and execution. The system 100 includes a shipment simulation system 112, a shipping operator 104, and a user device 109 accessible by a shipper 102. The shipper 102 can be, for example, a requestor of a shipment. Each of these components can communicate with one another, e.g., over a data communication network 106. In general, the system 100 can include more than one shipper 102, and more than one shipping operator 104 that communicate with one another. The network 106 can include public and/or private wired or wireless networks, and can include the Internet.

The user device 109 can be an electronic device such as a computing device. The user device 109 can be, for example, a desktop computer, a laptop computer, a smart phone, a cell phone, a tablet, a PDA, etc. The user device 109 is accessible by the shipper 102.

The shipment simulation system 112 can be a server system and can include one or more computing devices. In some implementations, the shipment simulation system 112 may be part of a cloud computing platform. The shipment simulation system 112 includes many (e.g., thousands) of computing nodes for performing simulation operations. The shipment simulation system 112 includes a shipping model 110 that can receive, as input, scheduled shipments 114, resource data 142, weather data 111, historical shipment data 122, shipment requests 108, or any combination of these. The shipment simulation system 112 produces simulation results 132 by executing a shipping model 110, which can include a resource availability model 115 and/or a shipment cancelation model 105, to predict shipments that will occur during various time periods in various geographic regions.

The shipper 102 can be any person or organization having interest in shipping goods. The shipper 102 can be, for example, a retail organization, a manufacturer of goods, a distributor of goods.

The shipping operator 104 can be, for example, an entity having an interest in or responsible for accommodating shipment requests. The shipping operator 104 can be, for example, a logistics organization, a postal service, a delivery service. The shipping operator can maintain and operate a shipment value model 144 that is used to generate shipment offers 130. The shipping operator 104 can provide shipment offers 130 to shippers, such as the shipper 102.

The system 100 can include one or more communication subsystems 118 for use by the shipment simulation system 112 to communicate with external parties. For example, the communication subsystems can receive the scheduled shipments 114 from the shipping operator 104 and the shipment request 108 from the shipper 102. The shipment simulation system 112 can also transmit data to the external parties using the communication subsystems. In some implementations, the communication subsystem 118 receives sensitive information from the parties locally or over a secure protocol. For example, the protocol can be a secure shell protocol (SSH) file transfer protocol, secure file transfer protocol (SFTP), gRPC (gRPC Remote Procedure Call) or other network transfer protocol.

In general, the shipper 102 can provide shipment request 108 to a shipment simulation system 112 through a user interface 135 provided through the user device 109. The shipping operator 104 can provide scheduled shipments 114 to the shipment simulation system 112. The shipping model 110 can provide simulation results 132 to the shipping operator 104.

FIG. 1 illustrates various events, shown as stages (A) to (H), with each representing a stage of shipping logistics simulation, planning, and execution. Stages (A) to (H) may occur in the illustrated sequence, or in a sequence that is different from the illustrated sequence. For example, some of the stages may occur concurrently.

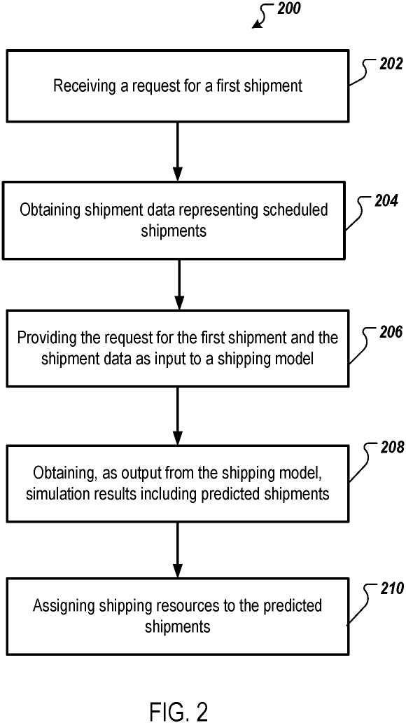

The system 100 can perform shipping logistics planning and execution using a process 200, shown in FIG. 2. The process 200 includes receiving a request for a first shipment (202). The request can be received by a requestor, such as the shipper 102 shown in FIG. 1.

For example, in stage (A) of FIG. 1, the shipment simulation system 112 receives the shipment request 108 from the user device 109. The user device 109 can send the shipment request 108 to the shipment simulation system 112, e.g., over the network 106. In some examples, the shipment request 108 includes a request for a shipment to occur during a first time duration, such as a particular hour, a particular portion of a day, a particular day, or a particular week.

The shipment request 108 can be input to the user device 109 by the shipper 102 through a user interface 135. The user interface 135 can include input fields for various data. For example, the user interface 135 can include an input field for any of: a type of goods to be shipped, a quantity of goods to be shipped, a resource needed to execute the first shipment; a first location from which the goods are to be shipped, a second location to which the goods are to be shipped, a target start time for the first shipment, a target time for delivery of the goods to the second location.

The process 200 includes obtaining shipment data representing scheduled shipments (204). In some examples, the shipment data represents scheduled shipments that are to occur during a second time duration that overlaps the first time duration. In an example the first time duration is a portion of a day, and the second time duration is the day. In another example, the first time duration is a day, and the second time duration is a week that includes the day.

For example, in stage (B) of FIG. 1, the shipping operator 104 sends the scheduled shipments 114 to the shipment simulation system 112, e.g., over the network 106. In some examples, data representing the scheduled shipments 114 can be stored in one or more databases operated by the shipping operator 104. For example, the shipping operator 104 can maintain a scheduled shipment database 148. In some examples, the scheduled shipments 114 can be updated routinely in order to reflect newly requested shipments and newly canceled shipments. In some examples, the scheduled shipments 114 can include shipments scheduled within a time duration, such as a month, two months, ninety days, a hundred days.

In some examples, the shipping operator 104 can provide the scheduled shipments 114 to the shipment simulation system 112 in response to the shipment simulation system 112 receiving the shipment request 108. For example, the shipment simulation system 112 may retrieve the scheduled shipments 114 from the shipping operator 104 based on the location of the requested shipment included in the shipment request 108. In some examples, the shipping operator 104 can provide the scheduled shipments 114 to the shipment simulation system 112 when updates are made to the scheduled shipments 114, such as when any scheduled shipments are reserved or canceled. In some examples, the scheduled shipments 114 may be scheduled, maintained, updated, and/or provided by an entity other than the shipping operator 104.

In stage (C) of FIG. 1, the shipping model receives, as input, weather data 111, historical shipment data 122, and resource data 142.

The shipment simulation system 112 receives weather data 111 from the weather service 120. The shipment simulation system 112 can receive, from the weather service, weather data at one or more locations of the requested shipment. In some examples, the shipment simulation system 112 can retrieve the weather data 111 based on one or more locations of the requested shipment included in the shipment request 108. The shipment simulation system 112 provides the weather data as input to the shipping model 110.

The weather service 120 can generate and/or provide weather data 111 to the shipment simulation system 112. In some examples, the weather service 120 provides historical weather data 111 to the shipment simulation system 112. For example, the weather data 111 can include time-varying temperatures, precipitation amounts, and atmospheric conditions. In some examples, the weather service 120 can provide averaged historical weather data. For example, the weather service 120 can provide temperatures for each hour of a simulated year, based on averaged historical temperatures. In some examples, the weather service 120 can provide weather data 111 for geographic locations where shipments occur. For example, the weather data 111 can include historical and/or predicted weather for a county, state, province, town, city, zip code area.

When running a simulation, the shipment simulation system 112 can retrieve weather data 111 for locations of the proposed shipment, as identified in the shipment request 108. For example, the shipment request 108 can include a street address, town, zip code, or latitude and longitude for starting and ending locations of the proposed shipment. The shipment simulation system 112 can retrieve the weather data 111 for geographic regions encompassing the starting and ending location from the weather service 120.

The shipping model 110 receives, as input, historical shipment data 122. The historical shipment data 122 can be collected over a period of time, e.g., a number of weeks, months, or years. In some examples, the historical shipment data 122 can be averaged historical shipment data. For example, historical shipment data 122 can include a transit time between a particular starting point and end point, averaged over multiple years. In another example, historical shipment data can include a number of canceled shipments during a particular day of the week, or during a particular week of the year, averaged over multiple years. In some examples, the historical shipment data 122 is provided by the shipping operator 104 and/or other shipping operators.

The shipment simulation system 112 receives resource data 142 from the shipping operator 104. In some examples, data representing the resource data 142 can be stored in one or more databases operated by the shipping operator 104. For example, the shipping operator 104 can maintain a resource database 146. The resource data 142 can identify shipping resources that can be used to execute shipments.

Shipping resources can include ground vehicles such as trains, trucks, vans, and cars. Shipping resources can include aerial vehicles such as airplanes, helicopters, and aerial drones. Shipping resources can include water vessels such as ships, boats, and barges. Shipping resources can include equipment that is used to store goods and move goods between transport vehicles. For example, shipping resources can include shipping containers and cranes. In some examples, a shipping resource is an autonomous vessel, craft, or vessel. In some examples, a shipping resource is a human-operated vessel, craft, or vessel.

The resource data 142 can include data that identifies, for multiple vehicle types, a number of each vehicle type that is available to execute shipments. The resource data 142 can include capabilities and characteristics of resources. For example, for a particular truck or model of truck, the resource data 142 can indicate values for fuel consumption, speed, range, and capacity of the truck. The resource data 142 can also indicate types of goods to be transported by a resource, and capabilities such as refrigeration capabilities of a resource.

The process 200 includes providing the request for the shipment and the shipment data as input to a shipping model (206). For example, in stage (D) of FIG. 1, the shipping model 110 receives, as input, the shipment request 108 and the scheduled shipments 114. In some examples, the shipment simulation system 112 runs the shipping model 110 in virtual machines or other secure execution environment instances, e.g., containers or sandboxes. The shipping model 110 can simulate shipments that are to occur during a time duration, the shipments including the first shipment specified by the shipment request 108 and the scheduled shipments 114.

The shipping model 110 includes a resource availability model 115. The resource availability model 115 is configured to determine likelihoods of execution of shipments based on the availability of resources. The shipping model 110 includes a shipment cancelation model 105. The shipment cancelation model 105 is configured to determine likelihoods of execution of shipments based on the likelihood that shipments will be canceled by their respective requestors.

In some implementations, the shipping model 110, the resource availability model 115, the shipment cancellation model 105, the shipment value model 144, or any of these can include machine learning models. The machine learning models can be trained using training data. The training data can include many (e.g., millions) of training samples.

In some implementations, a machine learning model is a deep learning model that employs multiple layers of models to generate an output for a received input. A deep neural network is a deep machine learning model that includes an output layer and one or more hidden layers that each applies a non-linear transformation to a received input to generate an output. In some cases, the neural network may be a recurrent neural network. A recurrent neural network is a neural network that receives an input sequence and generates an output sequence from the input sequence. In particular, a recurrent neural network uses some or all of the internal state of the network after processing a previous input in the input sequence to generate an output from the current input in the input sequence. In some implementations, a machine learning model is a convolutional neural network. In some implementations, the machine learning model is an ensemble of models that may include all or a subset of the architectures described above.

In some implementations, the machine learning model can be a feedforward autoencoder neural network. For example, the machine learning model can be a threelayer autoencoder neural network. The machine learning model may include an input layer, a hidden layer, and an output layer. In some implementations, the neural network has no recurrent connections between layers. Each layer of the neural network may be fully connected to the next, there may be no pruning between the layers. The neural network may include an ADAM optimizer, or any other multi-dimensional optimizer, for training the network and computing updated layer weights. In some implementations, the neural network may apply a mathematical transformation, such as a convolutional transformation, to input data prior to feeding the input data to the network.

In some implementations, the machine learning model can be a supervised model. For example, for each input provided to the model during training, the machine learning model can be instructed as to what the correct output should be. The machine learning model can use batch training, training on a subset of examples before each adjustment, instead of the entire available set of examples. This may improve the efficiency of training the model and may improve the generalizability of the model. The machine learning model may use folded cross-validation. For example, some fraction (the “fold”) of the data available for training can be left out of training and used in a later testing phase to confirm how well the model generalizes. In some implementations, the machine learning model may be an unsupervised model. For example, the model may adjust itself based on mathematical distances between examples rather than based on feedback on its performance.

The resource availability model 115 can be used to determine the likelihood of execution of the first shipment based on availability of resources. For example, the resource availability model 115 can receive, as input, the shipment request 108 for the first shipment. The shipment request 108 can specify a first location from which goods are to be shipped, a target start time for the first shipment, and a first resource that is needed to execute the first shipment.

The resource availability model 115 can receive, as input, resource data 142. The resource data 142 can indicate resources that are available to the shipping operator 104.

The resource availability model 115 can receive, as input, data representing scheduled shipments 114. The data representing the scheduled shipments 114 can indicate resources that are already assigned to scheduled shipments, as well as planned movements of the assigned resources.

The resource availability model 115 can provide, as output, a likelihood that the first resource will be available at the first location at or before the target start time. The shipping model 110 can determine, based at least in part on the likelihood that the first resource will be available at the first location at or before the target start time, the likelihood of execution of the first shipment.

The resource availability model 115 can be trained to predict availability of resources. In some examples, the resource availability model 115 is trained by providing, to the resource availability model, shipment data for multiple scheduled shipments 114. The resource availability model 115 outputs, for each of the scheduled shipments, resource prediction data indicating a likelihood that a resource needed to execute the scheduled shipment will be available to execute the scheduled shipment.

The shipment simulation system 112 can obtain availability data. In some examples, the availability data can be obtained as historical shipment data 122. The availability data can indicate, for each of the multiple scheduled shipments, whether the resource needed to execute the scheduled shipment was available to execute the reserved shipment. The shipment simulation system 112 can determine an error between the resource prediction data and the availability data. Parameters of the resource availability model 115 can be adjusted based on the error between the resource prediction data and the availability data in order to train the resource availability model 115. The trained resource availability model 115 can be used to determine likelihoods that resources will be available for scheduled shipments.

The shipping model 110 includes a shipment cancelation model 105. The shipment cancelation model 105 is configured to determine probabilities of cancelation of shipments. In some examples, the shipment cancelation model 105 is trained by providing, to the shipment cancelation model 105, shipment data for multiple scheduled shipments 114.

A shipment that is canceled can be a scheduled shipment for which the assigned resource is not used. In some examples, a shipment can be considered to be canceled if parameters of the shipment change by greater than a threshold amount compared to the scheduled parameter. For example, a threshold time change for starting a shipment may be four hours. A shipment that starts at a time that is less than four hours different from the scheduled start time can be considered to be executed. A shipment that starts at a time that is four or more hours different from the scheduled start time can be considered to be canceled.

In an example, a shipment may be scheduled to begin at a starting point prior to a target starting time, and end at an ending point. The shipment may be assigned to a particular truck. The goods that are to be shipped may be delayed by one day in arriving to the starting point, thus delaying the shipment such that the particular truck remains idle for the one day. The threshold parameter change for start time may be six hours. Thus, since the one-day delay is greater than the threshold parameter change, the shipment is considered to be canceled.

In another example, a shipment may be scheduled to start at a particular location. The shipment may be diverted to start from a different location. A threshold location change may be fifty miles. A shipment that starts from a location less than fifty miles of the scheduled location can be considered to be executed. A shipment that starts from a location at or greater than fifty miles from the scheduled location can be considered to be canceled.

The shipment data can include, for each scheduled shipment, a shipment offer that was selected by a requestor of the respective shipment. A shipment offer for a shipment can include a total cost value of the shipment, a value of at least one deposit for reserving the shipment; and a respective time when the at least one deposit is due for reserving the shipment. In some examples, the respective time when the at least one deposit is due for reserving the shipment is represented relative to the time of the shipment. For example, a deposit may be due one year before the shipment, six months before the shipment, one month before the shipment. The shipment cancelation model 105 outputs, for each of the scheduled shipments, cancelation prediction data indicating a likelihood that the scheduled shipment will be canceled by the respective requestor.

The shipment simulation system 112 can obtain cancelation data. In some examples, the cancelation data is obtained as historical shipment data 122. The cancelation data can indicate, for each of the scheduled shipments, whether the scheduled shipment was canceled by the requestor prior to execution. The cancelation data can indicate, for each scheduled shipment that was canceled by the requestor, a time of cancelation. For example, a time of cancelation for a shipment may be one month prior to a scheduled start time of the shipment, one week prior to the scheduled start time of the shipment, or one day prior to the scheduled start time of the shipment.

The shipment simulation system 112 can determine an error between the cancelation prediction data and the cancelation data. Parameters of the shipment cancelation model 105 can be adjusted based on the error between the cancelation prediction data and the cancelation data in order to train the shipment cancelation model 105. The trained shipment cancelation model 105 can be used to determine likelihoods that predicted shipments will be canceled by the respective requestors.

The shipping model 110 is configured to generate simulation results representing predicted movements of shipping resources executing scheduled shipments during the second time duration. The shipping model 110 can include probability functions for determining whether or shipments will occur. The probability functions can be learned over time, using shipment data. Once the probability functions are learned, the shipping model 110 can be used to generate highly reliable simulation results.

The shipping model 110 can be configured predict characteristics of shipments, such as whether scheduled shipments will occur, when scheduled shipments will begin, and when scheduled shipments will end. The shipping model 110 can also simulate aspects of shipments such as delays and detours due to weather and resource availability or non-availability. The shipping model 110 can generate the simulation results 132 using the resource availability model 115 and the shipment cancelation model 105.

The shipping model 110 can determine a likelihood of execution of shipments, such as the first shipment specified by the shipment request 108. For example, the shipping model 110 can determine, based on output from the resource availability model 115, the likelihood that the first resource will be available at the first location at or before the target start time. The shipping model 110 can determine, based on output from the shipment cancelation model, a likelihood of cancelation of the first shipment. The shipping model 110 can determine the likelihood of execution of the first shipment based at least in part on the determined availability of resources and likelihood of cancellation. The shipping model 110 can determine the likelihood of execution of the first shipment based at least in part on one or more of weather data 111, resource data 142, and historical shipment data 122.

After the second time duration, movements of the shipping resources that occurred during the second time duration can be determined. For example, the shipping operator 104 can provide, to the shipment simulation system 112, historical shipment data 122 representing executed movements of shipping resources over the second time duration. The shipment simulation system 112 can determine, for each predicted movement that was predicted by the shipping model 110, whether the predicted movement occurred. For each of the predicted movements that occurred, the shipment simulation system 112 can determine a respective time that the predicted movement occurred.

The shipment simulation system 112 can determine an error between the movements of the shipping resources that occurred during the second time duration and the predicted movements of the shipping resources during the second time duration. The shipment simulation system 112 can adjust parameters of the shipping model 110 based on the error between the movements of the shipping resources during the second time duration and the predicted movements of the shipping resources during the second time duration in order to train the shipping model 110. The trained shipping model 110 can be used to predict movements of shipping resources during scheduled shipments.

To reduce the risk that the shipping model 110 or its algorithms will be exposed to unauthorized disclosure from reverse engineering or otherwise, implementations of the shipment simulation system 112 include one or more of the following features. The shipping model 110 can be stored on the shipment simulation system 112 in encrypted form and decrypted only into memory of the shipment simulation system 112 when the shipping model 110 is to be executed. Optionally, the shipment simulation system 112 can execute the shipping model 110 in a secure execution environment that uses hardware-supported trusted execution environments of a CPU (central processing unit) or a secure element microprocessor for the protection of the shipping model 110 and the simulation results 132. In some examples, the shipment simulation system 112 allows output from the shipping model 110 to be sent only through a secure communication channel, which will only send it to the shipping operator 104.

In some implementations, the shipment simulation system 112 can run multiple shipping models in multiple secure execution environments. The shipment simulation system 112 can prevent instances of shipping models in each virtual machine from communicating with one another. Thus, during the shipment simulation system 112′s execution of the shipping models, the shipment simulation system 112 protects confidential data by preventing the shipping models from communicating with other components or services internal or external to the shipment simulation system 112 except as explicitly permitted.

The shipping model 110 simulates predicted shipments, including the requested shipment and the scheduled shipments, during a simulated time period. The simulated time period can be, for example, an hour, a day, multiple days, a week, multiple weeks, a month, or multiple months. The simulated time period can be, for example, a simulated period including the next one hundred days. In some examples, the shipping model 110 can generate simulation results 132 including predicted shipments for each day of the simulated period.

The process 200 includes obtaining, as output from the shipping model, simulation results including predicted shipments (208). For example, in stage (E) of FIG. 1, the shipping model outputs the simulation results 132 to the shipping operator 104.

The simulation results 132 can include predicted shipments during a particular time duration, such as the second time duration. The predicted shipments can include the scheduled shipments 114 and the first shipment specified by the shipment request 108. The simulation results 132 can include predicted movements of shipping resources executing the predicted shipments during the particular time duration.

The simulation results 132 can include predicted shipments over the course of the simulated period based on the scheduled shipments 114, the shipment request 108, the historical shipment data 122, the weather data 111, and the resource data 142. For example, predicted shipment may vary based on predicted seasonal effects (e.g., based on the weather data 111) and calendar effects (e.g., weekends, holidays).

The simulation results 132 can include, for each predicted shipment, a likelihood that the predicted shipment will be canceled by the requestor. In some examples, the simulation results include predicted locations of shipping resources during the second time duration.

The simulation results 132 can include, for each predicted shipment, at least one of: a type of goods to be shipped, a quantity of goods to be shipped, a first resource needed to execute the first shipment, a first location from which the goods are to be shipped, a second location to which the goods are to be shipped, a target start time for the first shipment, or a target time for delivery of the goods to the second location. In some examples, each predicted shipment includes a movement of at least one shipping resource.

In some examples, the shipment simulation system 112 performs many simulations of shipments during a particular time duration. For example, the shipment simulation system 112 can perform hundreds, thousands, or millions of simulations of shipments occurring during a particular time duration. Each simulation can be altered slightly from each other simulation according to different randomizations. The shipment simulation system 112 thus can generate a large amount of simulation data representing possible outcomes.

In some examples, the shipment simulation system 112 may determine a large number of possible outcomes (e.g., a million possible outcomes). The shipment simulation system 112 can analyze the outcomes to identify data points that have confidence values at or above a threshold confidence value. For example, the shipment simulation system 112 may determine that a particular scheduled shipment is executed on schedule in 96% of outcomes, and therefore has a 96% confidence level. The threshold confidence level may be 95%. Thus, the shipment simulation system 112 can output simulation results 132 representative of the particular shipment being executed on schedule. In this way, the shipment simulation system 112 can output simulation results 132 representing the outcomes with the highest confidence levels of occurring.

The shipping operator 104 can independently review the simulation results 132, e.g., as presented through a user interface 135 of a computer display. The simulation results 132 can include, for example, a table of predicted shipments. In some examples, the simulation results 132 include a two-dimensional and/or three-dimensional map view of predicted shipments.

The shipping operator 104 maintains a shipment value model 144. The shipment value model 144 can determine a value of the first shipment specified by the shipment request 108 based on the simulation results 132. In some examples, the shipment value model 144 uses the simulation results 132 to determine expected shipping resource supply and expected shipping resource demand during the first time period when the first shipment is to occur. Based on the expected shipping resource supply and expected shipping resource demand, the shipment value model 144 can determine the value of the first shipment.

In some examples, the simulation results 132 may indicate lower shipping resource usage expectancy during the first time period when the first shipment is to occur, and the shipment value model 144 may determine a lower value for the first shipment. In some examples, the simulation results 132 may indicate higher shipping resource usage expectancy during the first time period, and the shipment value model 144 may determine a higher value for the first shipment.

The shipping operator 104 generates a shipment offer 130. The shipment offer 130 can include a total cost value of the first shipment, based on the value determined by the shipment value model 144. In stage (F) of FIG. 1, the shipping operator 104 provides the shipment offer 130 to the device 109 associated with the shipper 102.

In some examples, the shipping operator 104 (e.g., a computing system associated with the shipping operator 104) provides multiple shipment offers 130 to the device 109. The device 109 can present the multiple offers on a display of the device. The device 109 can display the shipment offers 130 to the shipper 102 through the user interface 135. In some examples, the device 109 presents the shipment offers 130 on a graphical user interface 135 including selectable icons 138, with each selectable icon 138 being associated with a different one of the shipment offers.

Each shipment offer can include a total cost value of the first shipment. Each shipment offer can include a value of a deposit for reserving the first shipment. Each shipment offer can include a time when the deposit is due for reserving the first shipment.

In an example, a first shipment offer includes a cost of $1000, a deposit of $100, and a deposit date of one month prior to the start of the shipment. A second shipment offer includes a cost of $900, a deposit of $200, and a deposit date of two months prior to the start of the shipment. A third shipment offer includes a cost of $800, a deposit of $400, and a deposit date of four months prior to the start of the shipment.

A shipper who has a higher confidence that the shipment will not be canceled may be likely to select the third shipment offer, which has the lowest cost, but the largest deposit and the earliest deposit date. A shipper who has a lower confidence that the shipment will not be canceled may be likely to select the first shipment offer, which has the highest cost, but the smallest deposit and the latest deposit date. A shipper who has a confidence between the higher and lower confidence may be likely to select the shipment offer, which has a reduced cost compared to the first shipment offer, but a reduced deposit, and a later deposit, compared to the third shipment offer. Thus, the offer selected by the shipper can indicate a level of confidence that the shipment will not be canceled.

The device 109 can receive, through the user interface 135, a user selection of one of the selectable icons 138. In response to receiving the user selection of one of the selectable icons 138, the device 109 can send a shipment reservation 134 to the shipping operator 104. The shipment reservation 134 indicates acceptance of one of the shipment offers 130.

In stage (G) of FIG. 1, the shipping operator 104 receives the shipment reservation 134. Data from the shipment reservation 134 can be added to the scheduled shipment database 148. The data from the shipment reservation 134 can include the data included in the shipment request 108 as well as data indicating the shipment offer 130 that was selected by the shipper 102.

In some examples, the shipping operator 104 provides the scheduled shipments 114 from the scheduled shipment database 148, including the newly added shipment reservation 134, to the shipment simulation system 112. For example, the shipping operator 104 can provide the scheduled shipments 114 to the shipment simulation system 112 based on a schedule (e.g., once per hour, once per day) and/or in response to an event (e.g., a change in weather data 111, a new shipment request). In an example, the shipping operator 104 provides the scheduled shipments 114 to the shipment simulation system 112 daily, and the shipment simulation system 112 performs simulations for the next one hundred days. In some examples, the shipment simulation system 112 obtains the scheduled shipments 114 and performs simulations in response to receiving a shipment request.

The shipment simulation system 112 can perform simulations of the scheduled shipments 114, including the shipment reservation 134. The shipment cancelation model 105 can determine a likelihood of cancelation for the shipment reservation 134 based on the offer that was selected by the shipper 102. For example, the shipment simulation system 112 can provide, as input to the shipment cancelation model 105, the shipment offer 130 that was selected by the shipper 102 for the shipment reservation 134. The shipment simulation system 112 can receive, as output from the shipment cancelation model 105, the likelihood that the shipment reservation 134 will be canceled by the shipper 102.

The likelihood that the shipment reservation 134 will be canceled by the shipper 102 is information that the shipping operator 104 would not have access to nor could directly obtain. For example, the shipper 102 might not be willing to provide an estimate of the likelihood of cancelation. In some examples, the shipper 102 does not know the likelihood of cancelation. In some examples, the shipper 102 is not aware of factors that may affect the likelihood of cancelation, such as weather effects, market effects, and calendar effects on supply and demand for shipped goods.

The likelihood of cancelation for the shipment reservation 134 can be included in simulation results 132 generated by the shipment simulation system 112 for the scheduled shipments 114.

The process 200 includes assigning shipping resources to the predicted shipments (210). For example, in stage (H) of FIG. 1, the shipping operator 104 assign shipping resources 140 to the scheduled shipments in the scheduled shipment database 148 based on the simulation results 132.

The shipping operator 104 can output shipment assignments 136 to the shipping resources 140. The shipping assignments 136 can include, for each scheduled shipment in the scheduled shipment database 148, at least one assigned shipping resource. In some examples, the shipping assignments 136 include a first shipping resource assigned to a first leg of a shipment, and a second shipping resource assigned to a second leg of a shipment. The shipping assignments 136 can include starting and ending locations, and starting and ending times, for each leg of each shipment.

In some examples, a shipping assignment 136 can include an assignment of an autonomous vehicle to a scheduled shipment. The shipping operator 104 (e.g., a computing system associated with the shipping operator 104) can transmit instructions to the autonomous vehicle indicating the assignment to the scheduled shipment. In some examples, the shipping operator 104 can transmit the instructions to a communications device of the autonomous vehicle using wireless communications. The instructions can include navigation instructions directing the autonomous vehicle to arrive at a starting location for the shipment at or before a target starting time for the shipment. In some examples, the instructions include navigation instructions from the starting location for the shipment to an ending location for the shipment.

The disclosed system for managing shipping is resilient to change. Customers may experience changes in their circumstances that cause their shipping needs to change. Changes can include changes to timing or location of shipments and to value of the shipments. For example, when a ship carrying a good is delayed, there is high value to air-shipping a portion of the load. However, if the ship ends up arriving on time, the value of the air shipment drops. In another example, high retail demand may require a quick shipment to avoid running out of stock. The value of the shipment drops if demand flattens and stock levels stabilize.

Customers require ways to change their requested shipping services and have a high confidence that some mitigation will be successful. Shippers require ways to plan ahead for such changes and orchestrate their shipping resources to be both cost-effective and responsive to changes. Information that customers can provide to capture their shipping needs and how they may change is valuable and customers is able to share in the value (e.g., through lower shipping costs).

Customers and shippers can set up short-term or long-term agreements directly with each other or via an aggregating organization that operates short-term shipping markets or provides high-level shipping services. Long-term contracts provide stability, which enables long-term planning for all actors. However, with a long-term contract it can be difficult to manage short-term changes in shipping needs or shipment values. Short-term markets are somewhat effective at managing changes but face two major problems. First, the fragmented structure limits the ability to communicate information about shipping supply and demand to market participants. Further, because contracts are mostly signed with small shippers with little internal flexibility, unanticipated problems on their end, possibly due to changes by other customers, may result in the contracts not being honored.

The proposed platform can improve the shipping system’s ability to serve and coordinate its many actors. The platform can improve the interaction between shipping customers and aggregators while minimizing the impact to overall shipping systems. Shipping operators can implement the proposed techniques to mitigate risk (e.g., due to truck breakdown, delay in ship unloading, or new demands by long-term customers).

To effectively adjust to changing customer shipping needs it is important to provide customers with means to acquire new shipping contracts and give up the unneeded contracts. It is also important to provide customers with means to communicate which alternative shipping options may be needed in the future and to pay for having more available options. Customers benefit from providing information that enables shippers to plan more effectively.

To effectively adjust to changes in the value of shipments it is useful to provide customers with means to pay more or less to get better or worse guarantees on shipments that have grown or shrunk in value. A market can be managed by existing shipping aggregators in order to sell and trade shipping options.

The key attributes of the shipment in terms of a simple taxonomy can include the “from” and “to” destinations. For long haul shipments, the destinations can include city pairs. For short haul shipments, the destinations can include zip code pairs.

Attributes can also include a time of delivery, including start and end times at a coarse granularity (e.g., hourly). Attributes can also include features of the delivery (e.g., refrigerated, bulk vs. packaged).

Reliability attributes of the shipper can include one or more tiers of success (e.g., load picked up on-time, less than one hour late, same day). Shippers may be responsible for pickup, delivery, onloading, and offloading. For each tier, reliability attributes can include the price the shipper or customer pays if the tier is not achieved.

Contracts can be traded on a single market where any party may participate as a buyer or seller. Parties may create contracts in many ways. In some examples, parties can use out-of-market shipping resources (e.g., individual trucks from trucking companies) and package these as contracts with specific reliability guarantees.

In some examples, parties can buy one or more contracts on the market and resell them at a profit. For example, a company may expect a shipping demand to rise and thus buys shipping contracts cheaply one month in advance and resells them for a profit three weeks later. In another example, a shipping customer purchases a contract for a high-priority shipment but later discovers the value of the shipment has dropped. They then sell the contract to buy a lower-priced contract on another date. In another example, a customer has several factories that form a sequential production line, where components from one factory are shipped to another. Given the uncertainty in the amount of time needed for a factory to complete a step the customer buys a set of contracts with different pick-up times for each leg. As the completion times become more certain the customer sells off the contracts at the times that are not required at a mild loss.

In some examples, parties can purchase multiple contracts with somewhat different timings and reliability levels and resell them as a different set of contracts. In an example, a company caters to shipping customers who require very high reliability may purchase several lower-reliability contracts for the same route and repackage them as a single high-reliability contract to leverage the high probability that at least one of these contracts will succeed. In another example, a company has analyzed the possible paths of a hurricane and buys contracts for multiple ways to ship goods from city A to city B. Since each hurricane path will leave at least one of the purchased routes untouched, the company can resell the combined highly reliable contract at a higher price, knowing that the contract’s expensive penalty clauses are less likely to be triggered than the contracts by rivals who did not consider the hurricane.

The above approaches can be combined to create contracts that are a mix of out-of-market shipping resources and in-market contracts that may also be linked to decisions made within the seller’s wider supply chains. For example, the seller may own trucks and sell their capacity when they are not busy. Contract buyers and sellers may hedge their risk using non-shipment financial instruments like values of stocks and commodities, as well as re-insurance.

This approach satisfies criteria for an efficient shipping market, such as shipping confidently and efficiently. The contracts explicitly incorporate reliability guarantees and payments made when services are delayed or not provided. Additionally, the approach results in shipping that is more reliable, faster, or more specialized costing more, since no agent will pay more for a contract that is less useful than another contract. The approach also results in higher value shipments being delivered more reliably than lower value shipments. Contracts can be resold and customers have the opportunity to profitably sell contracts, from which they gain relatively little value, to companies that value these shipments more.

The approach also satisfies criteria for being resilient to change. Changes can be supported by buying a set of contracts and reselling the options that are not needed. In cases where uncertainty remains high even shortly before the shipment operation is needed, there might be no opportunity to resell and the cost of resilience will thus still be high in this case.

Shippers can observe demand for shipping services based on the number of contracts being purchased for a particular route and time. This gives them opportunity to assign more resources to service this demand, raise the price they charge for any unsold contracts, or lower the price on lower-demand routes to better utilize resources that cannot be repurposed to the high demand routes. Customers communicate with shippers by purchasing contracts. The customers benefit from lower costs because this information enables shippers to optimize their operations to service this particular shape of demand.

The disclosed techniques feature significant improvements to the way shipping is typically coordinated. The design permits agents to describe the wider context within which they operate. The market mechanism can enable agents to communicate the context for their shipping demand and supply in a standardized way, without revealing sensitive details about their internal operations. The mechanism provides different tradeoffs between capabilities and implementation complexity.

Customers often are not sure whether they will need a particular shipment to be performed. There may be ambiguity about the basic need for a delivery or uncertainty of its exact timing (e.g., pick up time for a truck depends on docking time of a ship) or endpoints (e.g. the delivery to a store may come from one of several warehouses). Thus, the market mechanism can be streamlined by providing customers a way to communicate the probability they will need a given shipment.

The platform can use incremental contracts, where customers can pay a small fee to buy the contract for a future shipment but then need to pay incremental fees at fixed checkpoints to ensure they keep the contract. If the fees are paid, then the contract remains available. Otherwise, the contract becomes void at a lower overall cost. This mechanism enables customers to clearly communicate their confidence that they will utilize a contract in a way that encourages honesty, because there is a financial benefit to being truthful, while still allowing customers to use market-based communication, e.g., by selling the contract, if the payment schedule does not match the pace at which the customer is able to predict future needs.

The platform can support cases where customers are not certain about details of the contract, such as the timing of a delivery pickup or the exact destination city, by supporting partially completed contracts. For example, a contract may specify the week when a pick-up is made, the specific origin city and a list of several destination cities. Then, at fixed time intervals before pick-up time, the customer will need to set the under-specified details. This approach communicates uncertainties faced by customers to shippers but at the cost of a more complex taxonomy for describing contracts, which reduces the liquidity of the contract trading market.

Customer needs for shipping are driven primarily by the dynamics of their wider supply chain, which includes production capabilities, various shipping and storage operations, as well as the demand for goods. The endpoints, timing, and cargo of each shipping operation depend on the shipping operation’s position within the supply chain. Thus, it can be difficult to plan the operation’s execution without knowing its context. The platform provides a way to communicate the key relevant details of the supply chain context without revealing sensitive information.

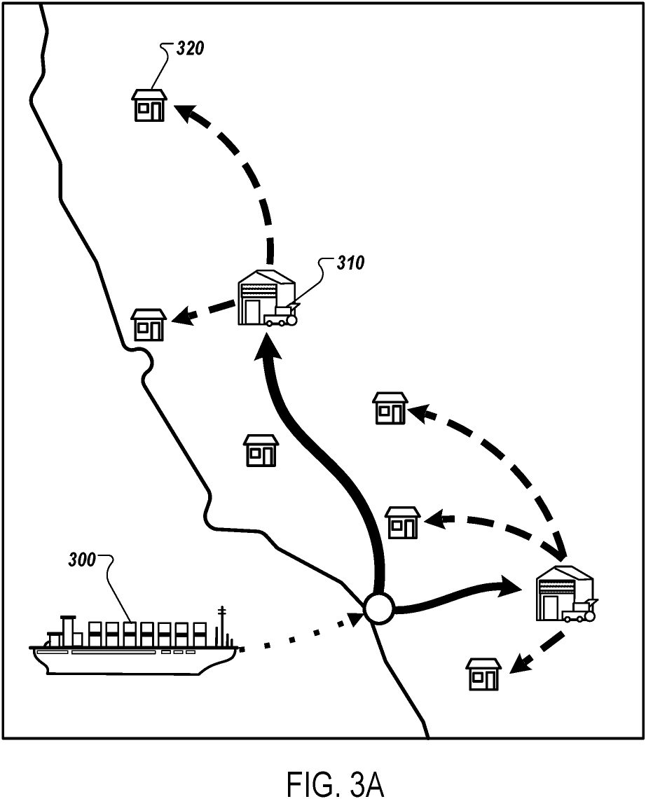

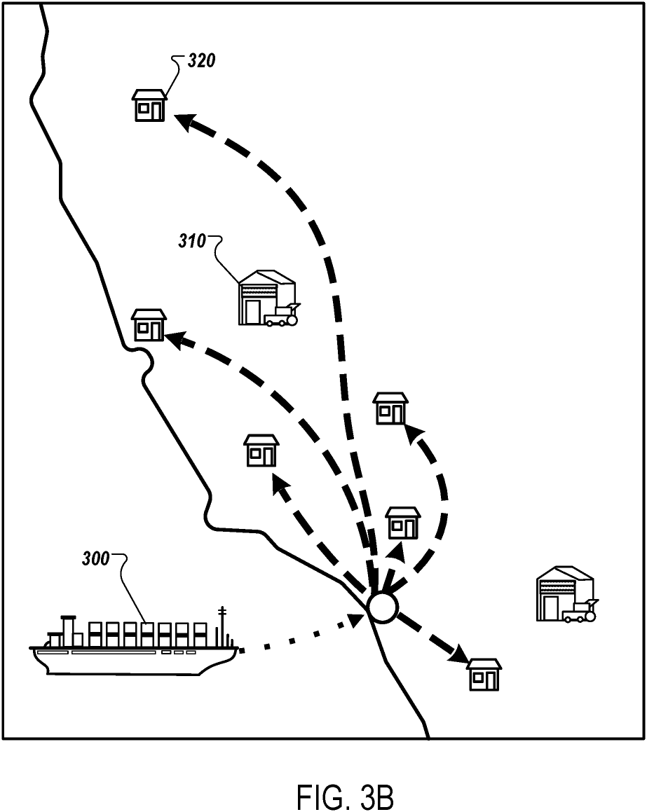

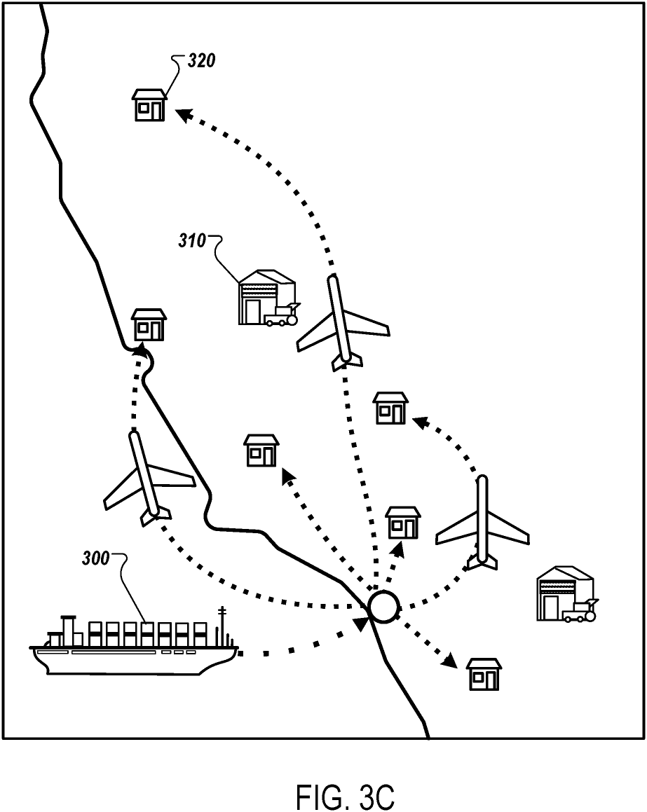

In an example scenario, a business intends to sell Halloween costumes manufactured in Asia at stores in North America before Halloween. Referring to FIG. 3A, the business can accomplish this objective by sending these goods from the factory via ship 300, then use large trucks to deliver the goods to regional warehouses, e.g., warehouse 310, and finally use smaller trucks to make short-distance deliveries to individual stores, e.g., store 320. Referring to FIG. 3B, if there is a one-week delay in the ship’s arrival, then the same goods will need to bypass the warehouse and be shipped directly long-distance to each store at a higher overall cost. Referring to FIG. 3C, if the delay lasts multiple weeks, the goods will need to be delivered to the stores by plane at a much higher cost to avoid the entire shipment going to waste.

The way each customer’s business objectives map to shipping actions can be represented by an algorithm. The algorithms track the timing of individual supply chain steps and optimize the shipping operations they perform to achieve its objectives. To efficiently and robustly execute these shipping operations it is necessary to determine how likely each operation is to be issued, as well as the correlation among the issuance of different operations. In the above example, key information includes that the customer will use either a single truck to each warehouse, multiple trucks to retail locations, or multiple plane shipments, but never a combination of the above three options. Further, if an aggregator had access to data indicating that the customer’s choices, as well as the choices of many other customers, depend on the arrival of a given ship, or on the delays at a given port, the aggregator would be able to plan for the configuration of transportation options needed under each delay scenario. Further, if an aggregator could predict the likely delays at a given port, they would be able to provision resources, such as trucks and planes, that would be sufficient to satisfy the likely patterns of shipment demand.

Shipping contracts can be extended with a specification of the condition that determines whether the contract will be used. For simplicity, contracts might not specify anything about unloading or the next step in the supply chain.

Example conditional actions are shown in Table 1.

TABLE 1

If ship arrives on target date: 1 truck from port of LA/LB to SFO
Else if ship arrives on < target_ date+7 days: 4 LTL loads from port of LA/LB to LAS, PHX, SAN, SFO
Else: 4 plane shipments from LAX: LAS, PHX, SAN, SFO
If store inventory for sparkling water is 50%: 1 truck from warehouse to store within 7 days
Else if store inventory is 25%: 1 truck from any regional warehouse (5 options) within 2 days
Else if store inventory < 5%: any LTL load from any warehouse (12 options) today
Next week’s (Feb in Michigan) weather forecast according to NOAA (public event):
If severe snowstorm: Extra packaged food deliveries to retail stores, Fewer fresh food deliveries
If mild winter cold: Normal deliveries
If warm temperatures: Extra deliveries of picnic foods and sunblock

Contracts may depend on publicly known events that are well-documented and forecasted via standard machine learning techniques (e.g., weather, ship arrivals, financial events). As their occurrence can be easily verified, participants will have no ability to gain or deny shipment operations unfairly. Further, aggregators will be able to use their forecasts of these events to compute the probability distribution of the possible shipment operations that may result from these contracts, enabling them to both plan ahead to service the contracts at a low cost, and to assign a price to each new contract.

Because contracts can be modeled probabilistically, they can be priced much like financial investments, based on the degree to which the new contract diversifies the aggregator’s obligations relative to other contracts. For example, consider a scenario where ship delays at a port require many goods to be shipped by plane. A contract for a truck shipment that occurs when ships are delayed (e.g., because it is not time sensitive) can be serviced very cheaply using idle trucking capacity that was arranged for the no-delay scenario. Similarly, consider shipments between the US and China, where the China to US route is very likely to be in much higher demand than the other direction. The addition of a new shipment from US to China can be accommodated at a very low cost and may even be something cargo shippers may pay for to provide ballast for the cargo ships. This is an application of an optimization model where the value of a new investment is judged based on how well it mitigates and complements the risks of an existing portfolio.

While aggregators strive to satisfy contracts with a high probability, a one hundred percent success rate will be infeasible in practice as it would require procuring enough shipment capacity to satisfy the worst-case scenario (referring to FIGS. 3A to 3C, this includes provisioning the truck for the shipment to the warehouse, the trucks for shipping to the stores, as well as the plans to ship to the stores). As such, in reality aggregators will target a lower success rate and use reinsurance to mitigate the risk of defaulting on some contracts.

While publicly known events form the most convenient basis for contracts, it is often useful for contracts to depend on events that are proprietary (e.g., inventory levels of a good at a store) or hard to track (e.g., stevedores’ speed in unloading a given container from a ship). Such events pose a challenge for because there is no incentive for customers to lie about them to exercise more expensive shipping operations, and it is hard for aggregators to forecast these events’ future occurrence. This can be handled in several ways. First, customers can be encouraged to link their hidden events to public events and penalize the customers if the correlation between the two drops below a given threshold. Higher thresholds, and thus, more predictability, will result in more efficient plans and thus lower prices for these contracts. Second, customers can be sold a certain number of tokens that allow the customer to declare that a given type of event has occurred. This will limit the degree to which customers may lie about the event and the price of these tokens can be adjusted to ensure profitability of these contracts. Further, by providing customers with a limited set of token categories, aggregators are able to develop techniques to forecast when they will be exercised based on the occurrence of public events.

The platform enables many different agents within the global supply chain to coordinate their actions to optimize the behavior of the overall supply chain. This goal is challenging because individual actors need to keep the details of their internal operations secret to maintain competitive advantage. Additionally, system-wide efficiency and reliability may not be in the best interest of all the actors who participate in the supply chain.

The algorithmic mechanism can enable different agents to coordinate their activities to improve system-wide efficiency in a way that enables them to be individually profitable, and keep their internal operational details secret.

An example algorithm is a futures market where “transport aggregator” agents post futures contracts for transportation operations, divided into a small number of categories: several hundred nationally, organized by city pairs, truck types, dates. Each contract includes a base price for performing the delivery, as well as the amount of money the shipper pays for failing to perform the delivery.

The base price communicates to buyers the supply of transportation resources of a given type. The failure penalty value communicates to the buyer the uncertainty the aggregator faces in providing the shipment. Higher uncertainty produces lower penalty relative to base price of the contract. When uncertainty is high it is also possible for shippers to offer contracts with high penalty by also raising the base price to absorb the risk.

The two prices capture the key attributes of the supply for shipping without revealing the aggregator’s network of trucks and routes, their internal constraints, or the constraints imposed by the shipping companies that own and operate the trucks.

Agents who purchase contracts communicate the demand for a certain variant of shipping services. Since these contracts can be traded, the value paid for similar contracts over time quantifies the changing value for shipments of this type, capturing any external drivers for shipping demand such as retail demand, factory delays, and competition from alternative shipment options (e.g., other routes or modes of transport). Further, changes in purchased contract values also reflect uncertainty about future demand. When uncertainty is high, customers can buy shipment options contracts for the multiple shipping routes that may be used, depending on possible demand scenarios. If uncertainty drops over time (e.g., the arrival time of the ship delivering goods to be trucked is becoming more certain as the ship draws closer to the port), customers will sell contracts that are not needed, dropping the price. If uncertainty rises (e.g., ocean storm forecast threatens to delay shipping), customers will buy additional contracts for the new routes that may be needed as a result, raising the price of these contracts.

The proposed approach standardizes complex information about the dynamics of supply chains into a simple taxonomy of city pairs, truck load types, and delivery (pick-up/drop-off) times. This simplification enables the operation of thick, highly liquid markets while empowering the individual agents to make accurate predictions about how to act within the larger supply chain to improve overall efficiency.

Buying and selling options contracts requires agents to be able to assign a fair price to the contracts that captures the state of the supply chain and their own interactions with the supply chain. This can be accomplished by training machine learning models to predict future time series of these phenomena. Agents who sell contracts will need to predict the cost of providing shipping services. For example, if these agents own their own shipping equipment this can be done by solving an optimization problem to optimally allocate these resources to a range of possible contracts. In contrast, if these agents are aggregators who buy shipping services on the spot market, the agents will need to forecast spot market prices on each route for the types of loads in which they are interested.

Agents who buy contracts will need to predict their own demand for shipping and the cost of options contracts for alternative routes. The former can be done via internal optimization models that describe the state of the customer’s internal supply chain. Alternatively, both tasks can be accomplished by building machine learning models to predict the time series of demand or shipping options prices.

Implementations of the subject matter and the functional operations described in this specification can be implemented in digital electronic circuitry, in tangibly-implemented computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible non-transitory program carrier for execution by, or to control the operation of, data processing apparatus. The computer storage medium can be a machine-readable storage device, a machine-readable storage substrate, a random or serial access memory device, or a combination of one or more of them.

The term “data processing apparatus” refers to data processing hardware and encompasses all kinds of apparatus, devices, and machines for processing data, including, by way of example, a programmable processor, a computer, or multiple processors or computers. The apparatus can also be or further include special purpose logic circuitry, e.g., a central processing unit (CPU), a FPGA (field programmable gate array), or an ASIC (application-specific integrated circuit). In some implementations, the data processing apparatus and/or special purpose logic circuitry may be hardware-based and/or software-based. The apparatus can optionally include code that creates an execution environment for computer programs, e.g., code that constitutes processor firmware, a protocol stack, a database management system, an operating system, or a combination of one or more of them. The present disclosure contemplates the use of data processing apparatuses with or without conventional operating systems, for example Linux, UNIX, Windows, Mac OS, Android, iOS or any other suitable conventional operating system.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, subprograms, or portions of code. A computer program can be deployed to be executed on one computer or on multiple computers that are located at one site or distributed across multiple sites and interconnected by a communication network. While portions of the programs illustrated in the various figures are shown as individual modules that implement the various features and functionality through various objects, methods, or other processes, the programs may instead include a number of sub-modules, third party services, components, libraries, and such, as appropriate. Conversely, the features and functionality of various components can be combined into single components as appropriate.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., a central processing unit (CPU), a FPGA (field programmable gate array), or an ASIC (application-specific integrated circuit).

Computers suitable for the execution of a computer program include, by way of example, can be based on general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer-readable media (transitory or non-transitory, as appropriate) suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The memory may store various objects or data, including caches, classes, frameworks, applications, backup data, jobs, web pages, web page templates, database tables, repositories storing business and/or dynamic information, and any other appropriate information including any parameters, variables, algorithms, instructions, rules, constraints, or references thereto. Additionally, the memory may include any other appropriate data, such as logs, policies, security or access data, reporting files, as well as others. The processor and the memory can be supplemented by, or incorporated in, special purpose logic circuitry.

To provide for interaction with a user, implementations of the subject matter described in this specification can be implemented on a computer having a display device, e.g., a CRT (cathode ray tube), LCD (liquid crystal display), or plasma monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user’s client device in response to requests received from the web browser.

The term “graphical user interface,” or GUI, may be used in the singular or the plural to describe one or more graphical user interfaces and each of the displays of a particular graphical user interface. Therefore, a GUI may represent any graphical user interface, including but not limited to, a web browser, a touch screen, or a command line interface (CLI) that processes information and efficiently presents the information results to the user. In general, a GUI may include a plurality of user interface (UI) elements, some or all associated with a web browser, such as interactive fields, pull-down lists, and buttons operable by the business suite user. These and other UI elements may be related to or represent the functions of the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (LAN), a wide area network (WAN), e.g., the Internet, and a wireless local area network (WLAN).

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of sub-combinations.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be helpful. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations, alterations, and permutations of the described implementations are within the scope of the following claims as will be apparent to those skilled in the art.

For example, the actions recited in the claims can be performed in a different order and still achieve desirable results.

Accordingly, the above description of example implementations does not define or constrain this disclosure. Other changes, substitutions, and alterations are also possible without departing from the spirit and scope of this disclosure.

What is claimed is:

1. A computer-implemented method, comprising:
receiving a request for a first shipment to occur during a first time duration, the request being provided by a requestor;
obtaining shipment data representing scheduled shipments to occur during a second time duration, the second time duration overlapping the first time duration;
providing the request for the first shipment and the shipment data as input to a shipping model;
obtaining, as output from the shipping model, simulation results including predicted shipments during the second time duration, the predicted shipments including the first shipment and the scheduled shipments, the simulation results including predicted movements of shipping resources executing the predicted shipments during the second time duration; and
assigning shipping resources to the predicted shipments based on the simulation results.

2. The method of claim 1, comprising determining a likelihood of cancelation of the first shipment, including:
providing, for presentation on a display of a computing device, a plurality of shipment offers;
receiving, from the computing device, data indicating a selected offer of one of the plurality of shipment offers; and
determining, based on the selected offer, a likelihood that the first shipment will be canceled by the requestor.

3. The method of claim 2, wherein:
providing, for presentation on the display of the computing device, the plurality of shipment offers comprises generating a graphical user interface displaying selectable icons, each selectable icon being associated with a different one of the plurality of shipment offers, and
receiving, from the computing device, the data indicating the selected offer of one of the plurality of shipment offers comprises receiving, through the graphical user interface, data indicating a selection, by the requestor, of one of the selectable icons.

4. The method of claim 2, wherein each shipment offer includes:
a total cost value of the first shipment;
a value of a deposit for reserving the first shipment; and
a time when the deposit is due for reserving the first shipment.

5. The method of claim 2, wherein determining, based on selected offer, the likelihood that the first shipment will be canceled by the requestor comprises:
providing, as input to a shipment cancelation model, the selected offer; and
receiving, as output from the shipment cancelation model, the likelihood that the first shipment will be canceled by the requestor.

6. The method of claim 1, wherein the simulation results include, for each predicted shipment, a likelihood that the predicted shipment will be canceled by the requestor.

7. The method of claim 1, wherein the shipping model includes a shipment cancelation model configured to determine probabilities of cancelation of shipments, the method comprising:
determining, for each of a plurality of reserved shipments and using the shipment cancelation model, cancelation prediction data indicating a likelihood that the reserved shipment will be canceled by the requestor;
obtaining cancelation data indicating, for each of the plurality of reserved shipments, whether the reserved shipment was canceled by the requestor;
determining an error between the cancelation prediction data and the cancelation data; and
adjusting parameters of the shipment cancelation model based on the error between the cancelation prediction data and the cancelation data; and
determining, using the shipment cancelation model, a likelihood that each of the predicted shipments will be canceled by the requestor.

8. The method of claim 7, wherein determining, for each of the plurality of reserved shipments and using the shipment cancelation model, the cancelation prediction data indicating the likelihood that the reserved shipment will be canceled by the requestor comprises:
providing, as input to the shipment cancelation model, a shipment offer selected for each of the plurality of reserved shipments.

9. The method of claim 1, comprising:
after the second time duration, determining movements of the shipping resources that occurred during the second time duration, including:
determining, for each predicted movement whether the predicted movement occurred, and;
determining for each of the predicted movements that occurred, a respective time that the predicted movement occurred;
determining an error between the movements of the shipping resources that occurred during the second time duration and the predicted movements of the shipping resources during the second time duration; and
adjusting parameters of the shipping model based on the error between the movements of the shipping resources during the second time duration and the predicted movements of the shipping resources during the second time duration.

10. The method of claim 1, wherein the simulation results include, for each of the predicted shipments, a probability function of whether or not the shipment will occur.

11. The method of claim 1, wherein the request for the first shipment includes at least one of:
a type of goods to be shipped;
a quantity of goods to be shipped;
a first resource needed to execute the first shipment;
a first location from which the goods are to be shipped;
a second location to which the goods are to be shipped
a target start time for the first shipment; or
a target time for delivery of the goods to the second location.

12. The method of claim 11, wherein the shipping model includes a resource availability model, the method comprising determining a likelihood of execution of the first shipment based on availability of resources, including:
providing, as input to the resource availability model, the request for the first shipment;
obtaining, as output from the resource availability model, a likelihood that the first resource will be available at the first location at or before the target start time; and
determining, based on the likelihood that the first resource will be available at the first location at or before the target start time, the likelihood of execution of the first shipment.

13. The method of claim 12, wherein determining the likelihood of execution of the first shipment comprises:
determining the likelihood that the first resource will be available at the first location at or before the target start time; and
determining the likelihood of cancelation of the first shipment.

14. The method of claim 1, comprising:
determining, for each of a plurality of reserved shipments and using a resource availability model, resource prediction data indicating a likelihood that a resource needed to execute the reserved shipment will be available to execute the reserved shipment;
obtaining availability data indicating, for each of the plurality of reserved shipments, whether the resource needed to execute the reserved shipment was available to execute the reserved shipment;
determining an error between the resource prediction data and the availability data; and
adjusting parameters of the resource availability model based on the error between the resource prediction data and the availability data; and
determining, using the resource availability model, a likelihood that each of the predicted shipments will be executed.

15. The method of claim 1, wherein:
each predicted shipment includes a movement of at least one shipping resource; and
the simulation results include predicted locations of shipping resources during the second time duration.

16. The method of claim 1, wherein:
the first time duration comprises a portion of a day and the second time duration comprises the day; or
the first time duration comprises a day and the second time duration comprises a plurality of days.

17. The method of claim 1, wherein the simulation results include, for each predicted shipment, at least one of:
a type of goods to be shipped;
a quantity of goods to be shipped;
a resource needed to execute the predicted shipment;
a first location from which the goods are to be shipped;
a second location to which the goods are to be shipped;
a target start time for the predicted shipment; or
a target time for delivery of the goods to the second location.

18. The method of claim 17, wherein assigning shipping resources to the predicted shipments comprises assigning an autonomous vehicle to a first predicted shipment, the method comprising:
transmitting, to a communications device of the autonomous vehicle using wireless communications, instructions to transit to the first location for arrival at or before the target start time for the first predicted shipment.

19. A system comprising one or more computers and one or more storage devices on which are stored instructions that are operable, when executed by the one or more computers, to cause the one or more computers to perform operations comprising:
receiving a request for a first shipment to occur during a first time duration, the request being provided by a requestor;
obtaining shipment data representing scheduled shipments to occur during a second time duration, the second time duration overlapping the first time duration;
providing the request for the first shipment and the shipment data as input to a shipping model;
obtaining, as output from the shipping model, simulation results including predicted shipments during the second time duration, the predicted shipments including the first shipment and the scheduled shipments, the simulation results including predicted movements of shipping resources executing the predicted shipments during the second time duration; and
assigning shipping resources to the predicted shipments based on the simulation results.

20. A non-transitory computer storage medium encoded with instructions that, when executed by one or more computers, cause the one or more computers to perform operations comprising:
receiving a request for a first shipment to occur during a first time duration, the request being provided by a requestor;
obtaining shipment data representing scheduled shipments to occur during a second time duration, the second time duration overlapping the first time duration;
providing the request for the first shipment and the shipment data as input to a shipping model;
obtaining, as output from the shipping model, simulation results including predicted shipments during the second time duration, the predicted shipments including the first shipment and the scheduled shipments, the simulation results including predicted movements of shipping resources executing the predicted shipments during the second time duration; and
assigning shipping resources to the predicted shipments based on the simulation results.
